(19) United States
(12) Patent Application Publication
(10) Pub. No.: US 2009/0068846 A1
(43) Pub. Date: Mar. 12, 2009

(54) COMPOSITIONS AND METHOD FOR TREATING A COPPER SURFACE

(76) Inventors: Catherine E. RADZEWICH, Iowa City, IA (US); David Maloney, Pleasanton, CA (US)

Correspondence Address: MORGAN LEWIS & BOCKIUS LLP, 1111 PENNSYLVANIA AVENUE NW, WASHINGTON, DC, 20004, US

(21) Appl. No.: 12/206,144

(22) Filed: Sep. 8, 2008

Related U.S. Application Data
(60) Provisional application No. 60/935,922, filed on Sep. 6, 2007.

(51) Int. Cl. H01L 21/306; C09D 7/12

(52) U.S. Cl. 438/754; 106/287.25; 106/287.2; 257/E21.224

(57) ABSTRACT

The present invention is directed to compositions for copper passivation and methods of use of such compositions.

### FIELD OF THE INVENTION

The present invention is directed to compositions for copper passivation and methods of use of such compositions.

### BACKGROUND

Semiconductor processing includes a number of processes and chemistries involved during processing. The front end manufacturing process, or wafer processing, includes wafer manufacturing, transistor formation (i.e., front-end of the line processing (FEOL)) and interconnect formation (i.e., back end of the line processing (BEOL)). The back end manufacturing process includes, for example, bumping and wafer level packaging. Throughout the front end and back end manufacturing processes, copper surfaces may be exposed to potentially damaging solutions and chemistries that could compromise the performance of the ultimate product. Historically, protection of the critical metals was addressed with a focus on the particular solutions the metal would contact in the particular processing step.

This focus causes a blinder effect, which is exacerbated by different chemical companies applying proprietary chemistries that may or may not impact processes and chemistries downstream.

In addition, each processing step may involve several substeps that use different chemistries for different purposes. For example, modern integrated circuits typically comprise millions of active devices on a single substrate, electrically interconnected through the use of single and multilevel interconnections including conductive lines and plugs (“vias”). Conventionally, integrated circuits include a semiconductor substrate and a plurality of sequentially formed dielectric layers and conductive patterns, including conductive lines, vias and interconnects. Typically, the conductive patterns on different layers, i.e., upper and lower layers, are electrically connected by a conductive interconnect or plug filling a via opening through the interlayer dielectric (“ILD”), while a conductive plug filling a contact opening establishes electrical contact with an active region on a semiconductor substrate, such as a source/drain region. A damascene technique can be employed to form interconnects by forming an opening or channel in the ILD and filling the opening with a conductive material, typically a metal. The metal typically fills the channel in the ILD and covers the field region atop the ILD between channels. Planarization typically is the next step, removing the metal in the field region, removing barrier/adhesion layers (if any), and providing a substantially planar surface for further coating and patterning. Each of these substeps may involve different chemistries and processing.

As integrated circuit manufacturing has become more complex and the dimensions of circuit elements fabricated on silicon or other semiconductor wafers have become smaller, continued improvement in techniques used to remove residues formed from such materials has been required. Moreover, in reduced geometry devices, the interconnect RC delay time may become the limiting factor of the device performance. This delay can be improved by combining low dielectric constant between tracks and the use of copper as a better conductor. Where copper and copper containing metallurgies are used in semiconductor applications, there is a need to protect the copper from corrosion and unwanted etching. Because of the need for more effective chemistries at each processing step throughout the manufacture of an electrical product, there is a trend toward customized chemistry approaches for each processing step. Because of this, there is a need for an additive that can protect copper in a broad spectrum of chemistries, processes, and process conditions.

This application is directed to solving the copper corrosion problem through the use of a passivating compound that surprisingly has been found to be useful and effective in a large number of compositions. The capability of passivating copper surfaces offers additional advantages in a variety of uses relating to semiconductor wafer processing.

This passivation capability further provides the advantage of being able to use more effective resist remover compositions which heretofore has been considered too aggressive toward copper metallurgies. Since copper can not easily be dry etched, the use of damascene or dual damascene structures is becoming a key solution to realize this integration. With the appearance of new materials such as organic polymers for inter metal dielectric material, and the need to etch complex layers of dielectric materials, photoresist removal and cleaning steps require a remover that is effective across a broad range of materials and/or residues. Accordingly, the development of new remover and/or cleaning chemistries and processes for their use, which are effective in removing a broad range of materials and are compatible with copper and is essential for process integration.

Many formulations have been developed to remove both positive and negative resist. A resist includes polymeric material, which may be crosslinked, ion implanted or hardened by baking. A simple combination of solvents may remove resists, though time and temperature constraints in the manufacturing process may preclude the use of such solvents. The substrate compatibility of the wafers with wet chemicals is also critical. For example, some compositions that are effective removers have produced corrosion on copper substrates. Other compositions that are less aggressive toward copper are less effective removers in general or are not effective over a broad spectrum of materials. Accordingly, there is a need for improvement in residue removal compositions and processes to minimize the need to sacrifice either cleaning efficiency or copper compound compatibility.

A variety of effective residue removal compositions and processes suitable for integrated circuit fabrication have been developed and marketed by EKC Technology, Inc. (hereinafter “EKC”), the assignee of the present application. Some of these compositions and processes are also useful for removing resists (e.g., photoresist), polyimide, residues, or other polymeric and organometallic layers from substrates in integrated circuit fabrication, and EKC has also developed a variety of compositions and processes specifically for removing such polymeric layers from substrates in integrated circuit fabrication. Additionally, EKC has developed a variety of compositions and processes to selectively remove specific substrate compositions from a substrate surface at a controlled rate. Such compositions and processes are disclosed in the following commonly assigned issued patents, examples of which are listed below:

U.S. Pat. No. 6,546,939 to Small et al., which issued on Apr. 15, 2003, entitled “Post clean treatment”;

U.S. Pat. No. 6,367,486 to Lee et al., which issued on Apr. 9, 2002, entitled “Ethylenediaminetetraacetic acid or its ammonium salt semiconductor process residue removal process”;

U.S. Pat. No. 6,313,039 to Small et al., which issued on Nov. 6, 2001, entitled “Chemical mechanical polishing composition and process”;

U.S. Pat. No. 6,276,372 to Lee, which issued on Aug. 21, 2001, entitled “Process using hydroxylamine-gallic acid composition”;

U.S. Pat. No. 6,248,704 to Small et al., which issued on Jun. 19, 2001, entitled “Compositions for cleaning organic and plasma etched residues for semiconductors devices”;

U.S. Pat. No. 6,242,400 to Lee, which issued on Jun. 5, 2001, entitled “Method of stripping resists from substrates using hydroxylamine and alkanolamine”;

U.S. Pat. No. 6,235,693 to Cheng et al., which issued on May 22, 2001, entitled “Lactam compositions for cleaning organic and plasma etched residues for semiconductor devices”;

U.S. Pat. Nos. 6,187,730 and 6,221,818, both to Lee, which issued on Feb. 13, 2001 and on Apr. 24, 2001, respectively, entitled “Hydroxylamine-gallic compound composition and process”;

U.S. Pat. No. 6,156,661 to Small, which issued on Dec. 5, 2000, entitled “Post clean treatment”;

U.S. Pat. No. 6,140,287 to Lee, which issued on Oct. 31, 2000, entitled “Cleaning compositions for removing etching residue and method of using”;

U.S. Pat. No. 6,121,217 to Lee, which issued on Sep. 19, 2000, entitled “Alkanolamine semiconductor process residue removal composition and process”;

U.S. Pat. No. 6,110,881 to Lee et al., which issued on Aug. 29, 2000, entitled “Cleaning solutions including nucleophilic amine compound having reduction and oxidation potentials”;

U.S. Pat. No. 6,000,411 to Lee, which issued on Dec. 14, 1999, entitled “Cleaning compositions for removing etching residue and method of using”;

U.S. Pat. No. 5,981,454 to Small, which issued on Nov. 9, 1999, entitled “Post clean treatment composition comprising an organic acid and hydroxylamine”;

U.S. Pat. No. 5,911,835 to Lee et al., which issued on Jun. 15, 1999, entitled “Method of removing etching residue”;

U.S. Pat. No. 5,902,780 to Lee, which issued on May 11, 1999, entitled “Cleaning compositions for removing etching residue and method of using”;

U.S. Pat. No. 5,891,205 to Picardi et al., which issued on Apr. 6, 1999, entitled “Chemical mechanical polishing composition”;

U.S. Pat. No. 5,672,577 to Lee, which issued on Sep. 30, 1997, entitled “Cleaning compositions for removing etching residue with hydroxylamine, alkanolamine, and chelating agent”;

U.S. Pat. No. 5,482,566 to Lee, which issued on Jan. 9, 1996, entitled “Method for removing etching residue using a hydroxylamine-containing composition”;

U.S. Pat. No. 5,399,464 to Lee, which issued on Mar. 21, 1995, entitled “Triamine positive photoresist stripping composition and post-ion implantation baking”;

U.S. Pat. No. 5,381,807 to Lee, which issued on Jan. 17, 1995, entitled “Method of stripping resists from substrates using hydroxylamine and alkanolamine”;

U.S. Pat. No. 5,334,332 to Lee, which issued on Aug. 2, 1994, entitled “Cleaning compositions for removing etching residue and method of using”;

U.S. Pat. No. 5,279,771 to Lee, which issued on Jan. 18, 1994, entitled “Stripping compositions comprising hydroxylamine and alkanolamine”;

U.S. Pat. No. 4,824,763 to Lee, which issued on Apr. 25, 1989, entitled “Triamine positive photoresist stripping composition and prebaking process”; and

U.S. Pat. No. 4,395,348 to Lee, which issued on Jul. 26, 1983, entitled “Photoresist stripping composition and method”.

The nucleophilic amines, organic solvents, and chelating agents disclosed in these applications, and other portions of the disclosures recognized by one of skill in the art as pertinent to the present invention, are incorporated herein for all purposes as if expressly contained herein. These compositions have achieved substantial success in integrated circuit fabrication applications.

Accordingly, there is also a need for the identification and understanding of synergistic interactions that allow the most effectiveness without compromising the surfaces that are intended to remain protected.

It is an objective of this application to provide an additive approach to treating copper surfaces to reduce corrosion throughout the semiconductor processing steps and allow for a uniform approach in a broad spectrum of chemistries that will enable the use of the most effective chemistries without compromising protection of the copper surfaces.

It is also an objective of this application to identify chemical synergies that provide a more favorable approach throughout the semiconductor processing steps.

It is further an objective of this invention to provide improved compositions for removing a broad range of resists, residues, polymers (e.g., organometallic), and planarization residues while inhibiting the corrosion of copper over a broad range of applications and processes, wherein the compositions are less aggressive toward copper and copper containing materials and suitable for meeting current semiconductor fabrication requirements.

These and other related objectives are attained through the use of the compositions and processes disclosed herein.

### SUMMARY OF THE INVENTION

One aspect of the present invention relates to the use of dithiocarbamate compounds, preferably ammonium diethyldithiocarbamate, piperidine dithiocarbamate, and morpholine dithiocarbamate, in semiconductor processing steps during the manufacture of a semiconductor product to inhibit copper containing surfaces involved in such processing steps.

In these uses, the dithiocarbamate compound is present in an amount of about 0.0001 to about 1 percent, more preferably about 0.001 to about 0.1 percent, and even more preferably about 0.002 to about 0.02 percent.

Another aspect of the present invention relates to compositions that passivate copper and methods of use of such compositions, for example, for removing a broad range of resists, residues, polymers (e.g., organometallic), and planarization residues. Said compositions are less aggressive toward copper and copper containing materials and suitable for meeting current semiconductor fabrication requirements.

Another aspect of the present invention is directed to copper passivating compositions and their use in semiconductor applications, wherein such compositions comprise at least one nucleophilic amine compound having oxidation and reduction potentials, at least one organic solvent which is miscible with the nucleophilic amine compound, water and, at least one chelating agent and at least one dithiocarbamate compound. The water can be added to the composition by itself or as a carrier for another component, such as the nucleophilic amine compound, i.e., the nucleophilic amine is present in aqueous solution.

Another aspect of the invention relates to a copper passivating composition comprising: a) one or more nucleophilic amines or salts thereof; b) one or more organic solvents; c) one or more chelating agents or salts thereof; d) one or more dithiocarbamates or salts thereof, and e) water.

Another aspect of the invention relates to a composition wherein the nucleophilic amine is selected from the group consisting of

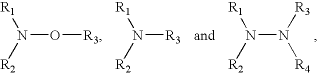

wherein R₁, R₂, and R₃ are independently hydrogen, an optionally substituted C₁-C₆ straight-, branched- or cyclo-alkyl, alkenyl, or alkynyl group; an optionally substituted acyl group, a straight or branched alkoxy group, an amidyl group, a carboxyl group, an alkoxyalkyl group, an alkylamino group, an alkylsulfonyl group or a sulfonic acid group.

Another aspect of the invention relates to a composition wherein the chelating agent is

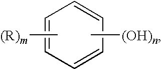

wherein n=1-4, m=2-5 and R is independently hydrogen, an optionally substituted C₁-C₆ straight-, branched- or cyclo-alkyl, alkenyl, or alkynyl group; an optionally substituted acyl group, a straight or branched alkoxy group, an amidyl group, a carboxyl group, an alkoxyalkyl group, an alkylamino group, an alkylsulfonyl group or a sulfonic acid group.

Another aspect of the invention relates to a copper passivating composition comprising a) hydroxylamine or a salt thereof; b) an alkanolamine; c) catechol or a salt thereof; d) a dithiocarbamate or a salt thereof, and e) water.

Another aspect of the invention relates to a composition wherein the nucleophilic amine is present in an amount of from about 1 to about 50 percent by weight, the organic solvent is present in an amount of from about 10 to about 80 percent by weight, the chelating agent is present in an amount of from about 0.1 to about 30 percent by weight, the dithiocarbamate is present in an amount from about 0.0001 to about 1 percent by weight, and the balance is water.

Another aspect of the invention relates to a composition of the present invention wherein the dithiocarbamate is selected from the group consisting of ammonium diethyldithiocarbamate, piperidine dithiocarbamate, and morpholine dithiocarbamate.

Another aspect of the invention relates to a composition comprising a) hydroxylamine or a salt thereof; b) a dithiocarbamate or a salt thereof; c) choline; and d) optionally an organic solvent.

Another aspect of the invention relates to a composition comprising a) a dithiocarbamate or a salt thereof; b) a hydroxy-substituted carboxylic acid; and c) water.

Another aspect of the invention relates to a method of removing one or more of resist, etching residue, and planarization residue from a copper containing substrate comprising contacting the substrate with the compositions of the invention.

Another aspect of the invention is a method of removing one or more of resist, etching residue, and planarization residue from a copper containing substrate.

A related U.S. patent application, now U.S. Pat. No. 5,279,771, which is incorporated herein by reference and which corresponds to published European Patent Application No. 485,161 A1, discloses hydroxylamine in combination with an alkanolamine which is miscible with the hydroxylamine as being useful to remove a resist from a substrate. It has now been found that by adding a dithiocarbamate compound, preferably ammonium diethyldithiocarbamate, piperidine dithiocarbamate, or morpholine dithiocarbamate, and another chelating agent, preferably a hydroxybenzene, more preferably catechol or gallic acid, copper compounds experience a lower corrosion or etching rate when contacting the composition than if either the dithiocarbamate compound or other chelating agent were used alone. This effect also applies where other compounds that may corrode or etch copper compounds are used, such as nucleophilic amine compounds.

While the nucleophilic amine compound must have the potential for reduction and oxidation, it is not required that reduction and oxidation actually occur in the use of the composition. Examples of nucleophilic amine compounds useful in the present invention include hydroxylamines, hydrazines, certain specified amines, and their derivatives as further described below. The organic solvent is not required to be an amine, but the presence of an amine solvent is preferred.

Further, it has been found that when a dithiocarbamate is present with another chelating agent, such as catechol or gallic acid, in an aqueous solution containing at least one nucleophilic amine compound and an organic solvent which is miscible with the nucleophilic amine compound, at least three benefits are achieved, namely: (1) the chelating agent assists in cleaning by retaining etching residue in the cleaning solution, thereby avoiding resettling of the residue onto the substrate; (2) the chelating agent serves as a stabilizing agent to provide long term effectiveness to the composition; and (3) the corrosion rate or etching rate of copper is diminished.

The first two benefits were known and disclosed in previous patents and applications owned by EKC, however, the third benefit was a surprising breakthrough and advantage, enhancing the application of a superior, broad spectrum nucleophilic amine remover formulation to applications involving copper, making the compositions of the present invention especially useful in removing resists, polymers, and residues from substrates using copper and copper compounds. Further, and surprisingly, it has been found that the effectiveness of the present remover concentrations is not negatively affected with the addition of dithiocarbamates, even when the residue, resist or polymer includes copper or a copper component.

The method of removing a resist or etching residue from a substrate using the compositions of the present invention also is advantageous in that complex process steps and equipment are not required. One method of use of the present invention involves contacting a substrate containing a resist or etching residue with the composition of the invention as described herein at a temperature and for a time sufficient to remove the particular resist or etching residue present. Although the compositions are particularly preferred for use where the substrate or surface contacting the composition involves copper or copper compounds, the compositions are effective removers when used with other substrates that do not contain copper, such as aluminum, tungsten, and dielectric containing materials.

In a preferred embodiment, the nucleophilic amine is hydroxylamine, the organic solvent is an alkanolamine, the chelating agent is catechol and the dithiocarbamate compound is ammonium diethyldithiocarbamate.

In another preferred embodiment the chelating agent is gallic acid and the dithiocarbamate compound is ammonium diethyldithiocarbamate.

Other preferred dithiocarbamate compounds include piperidine dithiocarbamate and morpholine dithiocarbamate.

In another preferred embodiment, the nucleophilic amine is present in an amount of about 1 to about 50 percent by weight, more preferably about 10 to about 30 percent; the organic solvent is present in an amount of about 20 to about 80 percent by weight; the chelating agent is present in an amount of about 2 to about 30 percent by weight, more preferably about 5 to about 15 percent; and the dithiocarbamate compound is present in an amount of about 0.0001 to about 1 percent, more preferably about 0.001 to about 0.1 percent, and even more preferably about 0.002 to about 0.02 percent.

One embodiment includes the use of dithiocarbamate to passivate copper surfaces using solution chemistries throughout processing of a semiconductor.

The compositions typically include dithiocarbamates contacted with copper surfaces. One embodiment of the present invention includes at least one nucleophilic amine compound which possesses reduction and oxidation potentials, at least one organic solvent which is miscible with the nucleophilic amine, water and, more than one chelating agent (e.g., dihydroxybenzene) and at least one dithiocarbamate compound (e.g., ammonium diethyldithiocarbamate, piperidine dithiocarbamate, or morpholine dithiocarbamate). The solutions are useful in applications involving copper where copper passivation is preferable, such as removing resists and etching residue from micro-circuitry during fabrication processes.

The present invention further relates generally to copper passivation compositions and methods of using such compositions for removal of resists, polymer, metal oxide, organic and organometallic contaminants, and/or metallic residues from semiconductor substrates.

### DETAILED DESCRIPTION

### Definitions

Unless otherwise specified, all percentages expressed herein should be understood to refer to percentages by weight. Also, the term “about,” when used in reference to a range of values, should be understood to refer to either value in the range, or to both values in the range.

As used herein, the phrases “contains substantially no” and “is substantially free from,” in reference to a composition means a negligible amount.

Preferably, when one of the aforementioned phrases is used, the composition is completely free of any added element specifically mentioned thereafter, or at least does not contain the added element in an amount such that the element affects the efficacy, storability, usability regarding necessary safety concerns, or stability of the composition.

Unless otherwise specified, and wherever possible, a compound should generally not be characterized under more than one enumerated element of the composition according to the invention. If a compound is capable of being characterized under, for example, two enumerated embodiments of the composition, such a compound may be characterized herein only under either one of the two enumerated elements, but not under both. At times, the distinction may be made based on the content of the compound in the composition. For instance, catechol or gallic acid can act primarily as a corrosion inhibitor at “high” concentrations, i.e., about 0.5% to 20%, or primarily as a metal chelator at “low” concentrations, i.e., in the ppm to 0.5 wt % range.

As used herein, the term “contacting” refers to any means of bringing the substrate or surface and the compositions of the present invention together physically and includes, but is not limited to, immersing, spraying, micro-droplet fogging, and the like.

Compositions containing dithiocarbamate compounds have been found to inhibit copper corrosion in processes relating to electronic component fabrication, including TFT LCD processes, printed circuit board processes, and processes relating to the fabrication of semiconductor substrates.

A first embodiment is a method of passivating copper in semiconductor processing applications by contacting a copper containing substrate with a dithiocarbamate compound, preferably a dithiocarbamate compound, more preferably ammonium diethyldithiocarbamate, piperidine dithiocarbamate, and morpholine dithiocarbamate.

Another embodiment is a method of passivating copper where the dithiocarbamate compound is admixed with a semiconductor processing composition prior to the use of such composition wherein said composition subsequently contacts a copper surface used in semiconductor processing applications, having a passivating effect on said copper surface.

In some embodiments, the composition further consists of a second corrosion inhibitor or chelating agent, such as a hydroxybenzene, for synergistic effect.

Another embodiment is a composition which is useful in methods for passivating copper as described in a number of applications involved in the electronic fabrication process, including removing one or more of resist, etching residue, polymer, and planarization residue, said composition comprising: a) one or more nucleophilic amines; b) one or more organic solvents; c) one or more chelating agents; d) one or more dithiocarbamate compounds, and e) water.

The compositions according to a preferred embodiment of this invention contain hydroxylamine, ammonium diethyldithiocarbamate, and catechol or gallic acid.

In some embodiments the composition is free of organic solvents. In other embodiments, the composition is free of nucleophilic amines.

### Nucleophilic Amines

Compounds suitable for use as the nucleophilic amine compound having oxidation and reduction potentials include certain amines, hydroxylamines, hydrazines and their derivatives as set forth below. The nucleophilic amine compound used in the present invention does not have to actually take part in oxidation or reduction during a cleaning or stripping process, but must only possess oxidation and reduction qualities in a cleaning or stripping environment. In one embodiment, suitable nucleophilic amine compounds useful in the present invention are compounds having the following formula or salts thereof:

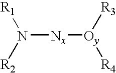

wherein R₁, R₂, R₃ and R₄ are either the same or different and selected from the group including hydrogen; a hydroxyl group; a substituted C₁-C₆ straight-, branched- or cyclo-alkyl, alkenyl or alkynyl group; a substituted acyl group; a straight or branched alkoxy group; an amidyl group; a carboxyl group; an alkoxyalkyl group; an alkylamino group; an alkyl sulfonyl group; or a sulfonic acid group, wherein x=0 when y=1; or x=0 or 1 when y=0; y=0 when x=1; or y=0 or 1 when x=0; provided that R₄ is present only when x=1. Specific examples of nucleophilic amine compounds are further described below.

In another embodiment, hydroxylamines suitable for use as the nucleophilic amine compound having reduction and oxidation potentials are represented by the following formula or salts thereof:

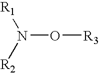

wherein R₁, R₂, and R₃ are independently hydrogen; a hydroxyl group; optionally a substituted C₁-C₆ straight-, branched- or cyclo-alkyl, alkenyl, or alkynyl group; optionally a substituted acyl group, straight or branched alkoxy group, amidyl group, carboxyl group, alkoxyalkyl group, alkylamino group, alkylsulfonyl group, or sulfonic acid group. Derivatives of these compounds—for example, the amides of the above described—are also suitable for use.

In another embodiment, amines suitable for use as the nucleophilic amine compound of the invention can be represented by the following formula:

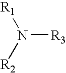

wherein R₁, R₂, and R₃ are independently hydrogen; optionally a substituted C₁-C₆ straight-, branched- or cyclo-alkyl, alkenyl, or alkynyl group; optionally a substituted acyl group, straight or branched alkoxy group, amidyl group, carboxyl group, alkoxyalkyl group, alkylamino group, or alkylsulfonyl group, sulfonic acid group; or the salt of such compounds.

Hydrazines suitable for use as the nucleophilic amine compound of the present invention can be represented by the following formula or salts thereof:

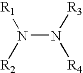

wherein R₁, R₂, R₃, and R₄ are independently hydrogen; a hydroxyl group; optionally a substituted C₁-C₆ straight, branched or cyclo alkyl, alkenyl, or alkynyl group; optionally a substituted acyl group, straight or branched alkoxy group, amidyl group, carboxyl group, alkoxyalkyl group, alkylamino group, alkylsulfonyl group, or sulfonic acid group.

The preferred nucleophilic amine compounds having reduction and oxidation potentials are alkoxy-substituted amines, hydroxylamine, alkyl- or carboxyl-substituted hydroxylamine, and alkyl- or carboxyl-substituted hydrazine. The most preferred compounds are hydroxylamine, N-methylhydroxylamine hydrochloride, N,N-diethylhydroxylamine, and methylhydrazine.

In some embodiments of the present invention, the composition is free of nucleophilic amine compounds.

### Organic Solvents

Organic solvents suitable for use in the present invention are miscible with the nucleophilic amine compound and are preferably water-soluble. Additionally, the organic solvent useful in the present invention preferably has a relatively high boiling point, such as for example 100° C. or above, and a high flash point, such as for example 45° C. or above.

Suitable organic solvents include alkanolamines and their derivatives. Additionally, non-amine solvents, such as dimethyl sulfoxide (DMSO), are suitable for use. Preferably an amine solvent is present alone or in combination with another solvent. Previously, it had been believed that an alkanolamine solvent had to be utilized. While an alkanolamine solvent is still a preferred solvent, it has now been found that other solvents are suitable for use when utilized with at least one nucleophilic amine compound having reduction and oxidation potentials.

Suitable alkanolamines are primary, secondary or tertiary amines and are preferably monoamines, diamines or triamines, and, most preferably, monoamines. The alkanol group of the amines preferably has from 1 to 5 carbon atoms.

Preferred alkanolamines suitable for use in the present invention can be represented by the chemical formula R₁R₂—N—CH₂CH₂—O—R₃ wherein R₁ and R₂ can be H, CH₃, CH₃CH₂ or CH₂CH₂OH and R₃ is CH₂CH₂OH.

Specific examples of suitable alkanolamines include monoethanol amine, diethanolamine, triethanolamine, tertiarybutyldiethanolamine isopropanolamine, 2-amino-1-propanol, 3-amino-1-propanol, isobutanolamine, 2-amino-2-ethoxy-propanol, and 2-amino-2-ethoxy-ethanol, which is also known as diglycolamine.

In some embodiments, the composition is free of alkanolamines.

Additional examples of organic solvents suitable for use in the composition of the present invention include N-methyl-2-pyrrolidinone, N,N-dimethylpropanamide, N,N-diethylformamide, ethylene glycol, ethylene glycol alkyl ether, diethylene glycol alkyl ether, triethylene glycol alkyl ether, propylene glycol, propylene glycol alkyl ether, dipropylene glycol alkyl ether, tripropylene glycol alkyl ether, N-substituted pyrrolidone, ethylenediamine, and ethylenetriamine. Additional polar solvents as known in the art can also be used in the composition of the present invention.

In some embodiments, the composition is free of organic solvents.

### Chelating Agents

Preferred chelating agents useful in the composition of the invention are hydroxybenzenes according to the following formula or salts thereof:

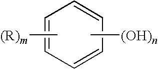

wherein n=1-4, m=2-5 and R is independently hydrogen, optionally a substituted C₁-C₆ straight-, branched- or cyclo-alkyl, alkenyl, or alkynyl group; optionally a substituted acyl group, straight or branched alkoxy group, amidyl group, carboxyl group, alkoxyalkyl group, alkylamino group, alkylsulfonyl group, or sulfonic acid group. The preferred compounds are the dihydroxybenzene isomers, and the alkyl substituted dihydroxybenzenes. The most preferred compounds are 1,2-dihydroxybenzene and 1,2-dihydroxy-4-t-butylbenzene.

Additional chelating agents, such as those known in the art, can also be used in the compositions of the present invention. For example, chelating agents which are metal ion free chelating agents can be utilized, such as thiophenol and its derivative according to the formula:

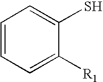

wherein R₁═OH or COOH; or ethylene diamine tetracarboxylic acid or its ammonium salts as shown in the following formula:

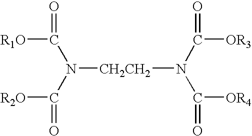

wherein R₁, R₂, R₃ and R₄ are independently H or NH₄⁺. Sodium, potassium or the like salts are not believed to be suitable for use based upon the understood mechanism of ionic contamination in a microcircuit as caused by cleaning. As evident from the above formula, mono-, di-, tri- and tetra-ammonium carboxylate salts are encompassed. The chelating agent, other than quaternary ammonium compounds, may be present in an amount of about 1 to about 30 percent by weight, more preferably about 2.5 to about 20 percent by weight, more preferably about 5 to about 15 percent by weight.

Additional suitable chelating agents include quaternary ammonium salts, which can be represented by the formula:

R₁R₂R₃R₄N⁺X⁻

wherein R₁, R₂, R₃, and R₄ are short chain alkyl or hydroxy alkyl groups, preferably having from 1 to 5 carbon atoms and wherein R₁, R₂, R₃, and R₄ can be the same or different, with the proviso that not all groups are hydroxy alkyl groups, and X includes, but is not limited to, halides (such as Cl⁻ and Br⁻) and hydroxide anion.

Preferred quaternary ammonium compounds include tetramethylammonium hydroxide (TMAH), choline, bis-choline compounds (e.g., bis-(2-hydroxy-ethyl)-dimethyl-ammonium ion) and the tris-choline compounds (e.g., tris-(2-hydroxy-ethyl)-methyl-ammonium ion), or a combination thereof.

In the compositions and processes of this invention, the choline compound includes, but is not limited to, tris-choline hydroxide, bis-choline hydroxide, tris-choline bicarbonate, bis-choline bicarbonate, tris-choline chloride, or bis-choline chloride. Preferably, the choline compound is bis-choline hydroxide and/or tris-choline hydroxide.

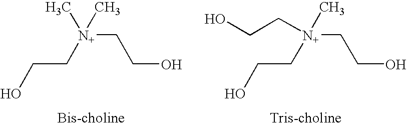

The quaternary ammonium compound may be present in an amount from about 0.1 to about 60 percent, more preferably from about 1 to about 20 percent by weight.

In some embodiments, the composition is free of quaternary ammonium compounds.

### Dithiocarbamate Compounds

The dithiocarbamate compound of the present invention is of the formula R₂NCS₂[M] wherein R is independently H, a C₁ to C₂₄ alkyl or cycloalkyl group, a C₆ to C₂₄ aryl, alkylaryl or aralkyl group, or NR₂ is a morpholino group; M is a cation (e.g., Na⁺, or NR₄⁺). A preferred dithiocarbamate compound is a compound of the formula:

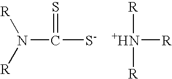

A most preferred dithiocarbamate compound is ammonium diethyldithiocarbamate, shown below:

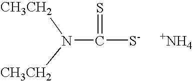

Without any restriction to a potential theory, it is believed that the dithiocarbamate compounds show a bidentate metal chelation through the terminal thio groups, which acts to lower the copper corrosion/etch rate during treatment.

In other embodiments of this invention, the compositions are substantially free of organic solvents. These embodiments are not generally preferred. In one embodiment, the compositions of the present invention are sugar and sugar alcohol free. In an alternate embodiment, compositions are substantially free of sulfones, imidazolidinones, and lactones. In another embodiment, compositions are substantially free of glycols. In yet another alternative embodiment of the invention, compositions are substantially free of sulfones, imidazolidinones, lactones, and glycols.

### Organic Acid

In one embodiment, the compositions of the present invention comprise, or alternatively, consists essentially of, organic acids, or mixtures of mineral acids and organic acids. Mineral acids may be boric acid, phosphoric acid, phosphorous acid, or phosphonic acid, more preferably phosphonic acid and/or phosphorus acid.

Preferred organic acids are carboxylic acids, e.g., mono-, di- and/or tri-carboxylic acids optionally substituted in a beta position with a hydroxy, carbonyl or amino group. Organic acid species useful in the composition include, but are not limited to, formic acid, acetic acid, propanoic acid, butyric acid and the like; hydroxyl-substituted carboxylic acids including, but not limited to, glycolic acid, lactic acid, tartaric acid and the like; oxalic acid; glycolic acid; amino substituted carboxylic acids including but not limited to glycine, hydroxyethylglycine, cysteine, alanine and the like; cyclic carboxylic acids including but not limited to ascorbic acid and the like; oxalic acid, citric acid, and mixtures thereof.

In one embodiment of the present invention, the remover composition comprises about 1 to about 20 percent by weight of an organic acid, from about 10 to about 1,000 ppm of a dithiocarbamate compound, and a balance of water.

More preferred are organic acids with a carbonyl group substituted on the carbon adjacent to the carboxyl group carbon. Exemplary preferred organic acids are oxalic acid, glycolic acid, periodic acid or mixtures thereof.

The acid is advantageously present at up to about 10%, preferably from about 0.1% to about 8%, for example from about 0.15% to about 6%.

### EXAMPLES

Exemplary embodiments of the present invention will be illustrated by reference to the following examples, which are included to exemplify, but not limit the scope of the present invention. In particular, although the examples are related to use of the compositions to remove residues, one of skill in the art would easily understand that such compositions can be used in many applications and the benefits relating to copper passivation are realized wherever copper compounds are contacted with such compositions.

### Example 1

### Glycolic Acid

Two compositions for removal of materials on a copper substrate were prepared with 10 wt % glycolic acid in water. The addition of 200 ppm ammonium diethyldithiocarbamate to one sample reduced the copper etch rate from 9.37 A/min to 1.53 A/min.

### Example 2

### Hydroxylamine/Choline (No Organic Solvent)

Two compositions for removal of materials on a copper substrate were prepared with 5 wt % hydroxylamine (50% aq); 25 wt % choline (40% aq), and 74 wt % water. To one sample, 20 ppm diethyldithiocarbamate was added. The addition of 20 ppm diethyldithiocarbamate reduced the copper etch rate from 6.4 A/min to 0.95 A/min.

### Example 3

### Hydroxylamine/Choline (No Organic Solvent)

Two compositions for removal of materials on a copper substrate were prepared with 12.5 wt % hydroxylamine (50% aq); 1 wt % choline (40% aq), and 86.5 wt % water. To one sample, 100 ppm diethyldithiocarbamate was added. The addition of 100 ppm diethyldithiocarbamate reduced the copper etch rate from 2.3 A/min to 0 A/min.

### Example 4

### Hydroxylamine/Choline (No Organic Solvent)

Two compositions for removal of materials on a copper substrate were prepared with 12.5 wt % hydroxylamine (50% aq); 1 wt % choline (40% aq), and 86.5 wt % water. To one sample, 100 ppm diethyldithiocarbamate was added. The addition of 100 ppm diethyldithiocarbamate reduced the copper etch rate from 2.9 A/min to 0 A/min. Note that the addition of 1000 ppm of ammonium bifluoride to the sample without diethyldithiocarbamate resulted in severe copper etching, while the addition to the sample with 100 ppm diethyldithiocarbamate resulted in no copper etching.

### Example 5

### Hydroxylamine/Choline (No Organic Solvent)

Two compositions for removal of materials on a copper substrate were prepared with 12.5 wt % hydroxylamine (50% aq); 1 wt % choline (40% aq), and 86.5 wt % water. To one sample, 20 ppm diethyldithiocarbamate was added. The addition of 20 ppm diethyldithiocarbamate reduced the copper etch rate from 2.9 A/min to 0 A/min. The initial etch with 20 ppm was less than with 100 ppm diethyldithiocarbamate.

### Example 6

### Hydroxylamine/Choline (No Organic Solvent)

Two compositions for removal of materials on a copper substrate were prepared with 16 wt % hydroxylamine (50% aq); 4.7 wt % choline (40% aq), and 78.5 wt % water. To one sample, 20 ppm diethyldithiocarbamate was added. The addition of 20 ppm diethyldithiocarbamate reduced the copper etch rate from 5.7 A/min to 0 A/min.

### Example 7

### Hydroxylamine/Organic Solvent

Two compositions for removal of materials on a copper substrate were prepared with 35 wt % hydroxylamine (50% aq); 5 wt % catechol; and 60 wt % 2-amino-2-ethoxy ethanol (DGA or diglycolamine). To one sample 200 ppm diethyldithiocarbamate was added. The addition of 200 ppm diethyldithiocarbamate reduced the copper etch rate from greater than 10 A/min to 0.9 A/min.

### Example 8

### Hydroxylamine/Organic Solvent

Two compositions for removal of materials on a copper substrate were prepared with 35 wt % hydroxylamine (50% aq); 60 wt % 2-amino-2-ethoxy ethanol (DGA or diglycolamine), and a balance water. To one sample 200 ppm diethyldithiocarbamate was added. The addition of 200 ppm diethyldithiocarbamate resulted in a reduction of the copper etch rate.

As emphasized above, the applications described herein are not intended to be limiting and could include other applications, such as wafer level packaging rework, the removal of solder bumps, photoresist removal or other electronic fabrication processes where Cu or other metals are exposed during the processing.

The wafer surface after being treated with the dithiocarbamate compound (e.g., diethyldithiocarbamate) and a chelating agent (e.g., catechol) as described above will be resistant to corrosion. Those skilled in the art will recognize other copper-related surfaces that come in contact, or could be made to come in contact, with the cleaning solution of the present invention that are also effectively passivated with the dithiocarbamate and chelator compounds. For example, the corrosion inhibiting compounds of the present invention could also be used to not only inhibit substrate corrosion, but also inhibit the corrosion of copper containing machinery employed during cleaning processes and thereby prolong the life of such machinery.

It should be borne in mind that the corrosion inhibiting compounds of the present invention may include other corrosion inhibiting compounds in addition to the dithiocarbamate compound, such as those found in U.S. Pat. No. 6,110,881, which is incorporated herein by reference, azole compounds, 1-pyrrolidine carbodithioate NH⁺ and the like, tetraethylthiuram disulfide and the like. By way of example, representative azole compounds include triazoles, pyrazoles, imidazoles, isoxazoles, oxazoles, isothiazoles and thiazoles. In a preferred embodiment, however, the corrosion inhibiting compounds of the present invention are dithiocarbamate compounds. The above list of corrosion inhibitors should not be construed as an exhaustive list and those skilled in the art will recognize that other compounds may be used as corrosion inhibitor compounds of the present invention.

Although the foregoing invention has been described in some detail for purposes of clarity of understanding, it will be apparent that certain changes and modifications may be practiced within the scope of the appended claims. For example, while the specification describes introducing the corrosion inhibiting compound for semiconductor cleaning and stripping, there is no reason why in principle the corrosion inhibiting compound of the present invention cannot be introduced in other application involving copper and hydroxylamine, such as a post-CMP application. Therefore, the present embodiments are to be considered as illustrative and not restrictive, and the invention is not to be limited to the details given herein, but may be modified within the scope of the appended claims.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

1. A copper passivating composition comprising:
a) one or more nucleophilic amines or salts thereof;
b) optionally one or more organic solvents;
c) optionally one or more chelating agents or salts thereof;
d) one or more dithiocarbamates or salts thereof, and
e) water.

2. The composition of claim 1, wherein the nucleophilic amine is selected from the group consisting of 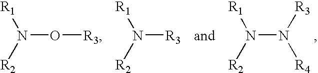
wherein R₁, R₂, and R₃ are independently hydrogen, an optionally substituted C₁-C₆ straight-, branched- or cyclo-alkyl, alkenyl, or alkynyl group; an optionally substituted acyl group, a straight or branched alkoxy group, an amidyl group, a carboxyl group, an alkoxyalkyl group, an alkylamino group, an alkylsulfonyl group or a sulfonic acid group.

3. The composition of claim 1, wherein the nucleophilic amine is hydroxylamine.

4. The composition of claim 1, wherein the organic solvent is an alkanolamine.

5. The composition of claim 1, wherein the chelating agent is 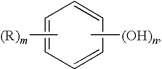
wherein n=1-4, m=2-5 and R is independently hydrogen, an optionally substituted C₁-C₆ straight-, branched- or cyclo-alkyl, alkenyl, or alkynyl group; an optionally substituted acyl group, a straight or branched alkoxy group, an amidyl group, a carboxyl group, an alkoxyalkyl group, an alkylamino group, an alkylsulfonyl group or a sulfonic acid group.

6. The composition of claim 1, wherein the chelating agent is catechol.

7. The composition of claim 1, further comprising choline.

8. The composition of claim 7 comprising
a) hydroxylamine or a salt thereof;
b) a dithiocarbamate or a salt thereof;
c) choline; and
d) optionally an organic solvent.

9. The composition of claim 1 comprising
a) hydroxylamine or a salt thereof as the nucleophilic amine;
b) an alkanolamine as the organic solvent;
c) catechol or a salt thereof as the chelating agent;
d) a dithiocarbamate or a salt thereof, and
e) water.

10. The composition of claim 1, wherein the nucleophilic amine is present in an amount of from about 1 to about 50 percent by weight.

11. The composition of claim 1, wherein the organic solvent is present in an amount of from about 10 to about 80 percent by weight.

12. The composition of claim 1, wherein the chelating agent is present in an amount of from about 0.1 to about 30 percent by weight.

13. The composition of claim 1, wherein the dithiocarbamate is present in an amount from about 0.0001 to about 1 percent by weight.

14. The composition of claim 1, wherein the nucleophilic amine is present in an amount of from about 1 to about 50 percent by weight, the organic solvent is present in an amount of from about 10 to about 80 percent by weight, the chelating agent is present in an amount of from about 0.1 to about 30 percent by weight, the dithiocarbamate is present in an amount from about 0.0001 to about 1 percent by weight, and the balance is water.

15. A copper passivating composition comprising:
a) a dithiocarbamate or a salt thereof;
b) a hydroxyl-substituted carboxylic acid; and
c) water

16. The composition of claim 15, wherein the hydroxyl-substituted carboxylic acid is glycolic acid.

17. The composition of claims 1 or 15, wherein the dithiocarbamate is selected from the group consisting of ammonium diethyldithiocarbamate, piperidine dithiocarbamate, and morpholine dithiocarbamate.

18. A method of removing one or more of resist, etching residue, and planarization residue from a copper containing substrate comprising contacting the substrate with the composition of claims 1 or 15.

19. A method of passivating a copper containing substrate comprising contacting the substrate with the composition of claims 1 or 15.
